(19) United States
(12) Patent Application Publication
(10) Pub. No.: US 2026/0333666 A1
(43) Pub. Date: Oct. 22, 2026

(54) DRAM DEVICE HAVING 3.5F2 STRUCTURE LAYOUT

(71) Applicant: TAESUNG ENVIRONMENTAL RESEARCH INSTITUTE CO., LTD., Ulsan (KR)

(72) Inventors: Gi Yeol YUN, Ulsan (KR); Seok Man KIM, Ulsan (KR); Chai Rok LIM, Ulsan (KR); Hyeok-Je JEONG, Gimhae-si (KR); Myung-Kon JO, Ulsan (KR)

(73) Assignee: TAESUNG ENVIRONMENTAL RESEARCH INSTITUTE CO., LTD., Ulsan (KR)

(21) Appl. No.: 19/401,860

(22) Filed: Nov. 26, 2025

(30) Foreign Application Priority Data
Apr. 17, 2025 (KR) 10-2025-0050482

(51) Int. Cl. H10B 12/00

(52) U.S. Cl. CPC H10B 12/315

(57) ABSTRACT

A DRAM device including a substrate; a plurality of channel patterns arranged in a honeycomb structure on the substrate; a plurality of bit lines in contact with one side surface of the lower electrode, oriented in a first horizontal direction; a plurality of word lines in contact with the body region; and a gate insulating pattern positioned between the plurality of channel patterns and the plurality of word lines; wherein the plurality of word lines include first and second word lines arranged at mutually different heights, and the first and second word lines are alternately provided in the first horizontal direction; a plurality of channel patterns in contact with a single word line are arranged in a straight line, a plurality of channel patterns in contact with a single bit line are arranged in a zigzag, and having a layout of a 3.5F2 structure.

### CROSS-REFERENCE TO RELATED APPLICATION

This application claims priority to and the benefit of Korean Patent Application No. 10-2025-0050482, filed on Apr. 17, 2025, the disclosure of which is incorporated herein by reference in its entirety.

### BACKGROUND

### 1. Field of the Invention

The present invention relates to a DRAM device, and more particularly, to a DRAM device having a layout of a 3.5F2 structure (an example of sub-4F2 structure).

### 2. Discussion of Related Art

A DRAM cell has a 1T1C (one transistor-one capacitor) structure that stores and reads data, and is composed of a capacitor and a transistor (Non-Patent Literature 1). In a DRAM cell, the capacitor stores charge to preserve logical information, and the transistor is controlled to be turned on/off by a word line to provide a data path between the capacitor and a bit line. The bit line is a data transmission path, and the word line serves as a signal line that activates or deactivates the transistor as the gate of the transistor. In such a configuration, the operation of the DRAM cell is divided into writing, reading, and refreshing, and weak signal amplification and periodic data recharging are performed through a Sense Amplifier and Refresh Circuitry, etc.

Meanwhile, the main operation process of a DRAM cell can be divided into a Write Operation, a Read Operation, and a Refresh Operation.

The write operation is an operation of storing data, wherein a word line is activated, turning on the access transistor, input data is transferred to the capacitor via the bit line (in the case of logic ‘1’, the capacitor is charged with positive charge, and in the case of logic ‘0’, the capacitor is charged with negative charge), and as the word line is deactivated, the access transistor is turned off, and the data is stored in the capacitor.

The read operation is an operation of reading data, wherein the word line is activated, turning on the access transistor, the charge state of the capacitor is transferred to the bit line (if there is positive charge in the capacitor, a slight voltage rise is detected in the bit line, and if there is negative charge in the capacitor, a slight voltage drop is detected in the bit line), and the data in the bit line is amplified by a Sense Amplifier and converted into a readable signal.

Since the capacitor of a DRAM undergoes natural discharge over time, periodic refreshing is necessary to avoid losing data, and this is called a refresh operation. The refresh period is generally in units of several milliseconds (ms), and after reading the cell's data, the same data is rewritten to replenish the charge.

Main characteristics of a DRAM cell include: being a volatile memory in which data is lost as the capacitor's charge is discharged when power is cut off; enabling high integration density, fast access, and operation with low power due to the simple 1T1C structure; and requiring a regular refresh period to maintain data, which consumes additional power.

Main considerations during DRAM cell operation include: as DRAM cells become smaller, the capacitor capacity decreases, making it difficult to store sufficient charge, which can reduce data stability; interference (coupling noise) may occur between adjacent bit lines; and a margin (sensing margin) to distinguish signals from noise during read operations is required.

Through these operations, the DRAM cell stores, reads, and maintains data, performing its role as a high-density and high-performance memory.

As the integration density of semiconductor memory devices increases, the cell structure has been continuously scaled down from 8F² and 6F² to 4F² in order to reduce the planar area occupied by each unit memory cell. In response, various technologies have been proposed to implement components such as transistors, bit lines, word lines, and capacitors within the 4F² cell structure. In particular, as one way to reduce the unit cell area, a DRAM device including a vertical channel transistor, which induces a vertical channel by arranging the source and drain regions vertically, has been researched. Chung et al. proposed a new DRAM cell with a 4F² structure applying a vertical pillar transistor (VPT) (Non-Patent Literature 2). It was expected that using such a vertical channel transistor could increase cell area efficiency.

However, in the vertical channel transistor of Non-Patent Literature 2, as the channel pillar and the cell capacitor are in direct contact, leakage current flows during data storage, resulting in a short retention time, which requires frequent refreshing and increases power consumption. Meanwhile, in the semiconductor device field, a reduction in the minimum feature size (F) and smaller cell layouts are continuously being pursued to increase the capacity per unit area. However, the minimum spacing between wiring lines formed on the same plane, such as word lines, has faced physical limits in the manufacturing process, making it difficult to further increase the capacity per unit area with the device of Non-Patent Literature 2 alone.

Furthermore, in conventional fine processes, when the bit line is formed as a diffusion region within the substrate, there is a problem of increased signal transmission delay (RC delay) and reduced sensing margin due to high resistance and large parasitic capacitance. (Non-Patent Literature 1) Robert H. Dennard, “Operation of a One-Transistor Cell Used in a High-Density DRAM”, IEEE Journal of Solid-State Circuits, Vol. SC-9, No. 5, Oct. 1974 (Non-Patent Literature 2) Chung et al., “4F2 DRAM Cell with Vertical Pillar Transistor (VPT)”, 2011 Proceedings of the European Solid-State Device Research Conference (ESSDERC), 2011

### SUMMARY OF THE INVENTION

One of the objects of the present invention is to provide a vertical channel transistor that can reduce the resistance and RC delay of a bit line and improve the sensing margin by forming the bit line from a conductive material such as metal or silicide, and a DRAM device including the same.

Another object of the present invention is to provide a DRAM device that can increase the cell capacity per unit area through a multilayer word line structure formed at different heights.

According to one aspect, there is provided a DRAM device, comprising: a substrate; a plurality of channel patterns arranged in a honeycomb structure on the substrate, each extending in a vertical direction, wherein each channel pattern includes an upper electrode and a lower electrode, and a region between the upper electrode and the lower electrode is a body region; a plurality of bit lines in contact with one side surface of the lower electrode, oriented in a first horizontal direction, and arranged parallel to each other at a predetermined interval; a plurality of word lines in contact with the body region, oriented in a second horizontal direction perpendicular to the first horizontal direction, and arranged parallel to each other at a predetermined interval; and a gate insulating pattern positioned between the plurality of channel patterns and the plurality of word lines; wherein the plurality of word lines include first and second word lines arranged at mutually different heights, and the first and second word lines are alternately provided in the first horizontal direction; and wherein a plurality of channel patterns in contact with a single word line are arranged in a straight line, a plurality of channel patterns in contact with a single bit line are arranged in a zigzag, and having a layout of a 3.5F2 structure.

In one embodiment, each of the plurality of channel patterns may include an upper electrode and a lower electrode, and the lower electrode may be in contact with the bit line.

In one embodiment, the bit line may include a metal or silicide material.

In one embodiment, the device may further include a gate electrode provided between the word line and the gate insulating pattern.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of a vertical channel transistor according to one embodiment of the present invention.

FIG. 2 is a cross-sectional view taken along line A-A′ of FIG. 1.

FIG. 3 is a cross-sectional view taken along line B-B′ of FIG. 1.

FIG. 4 is a schematic plan view of the vertical channel transistor of FIG. 1.

FIG. 5 is a perspective view of a DRAM device including the vertical channel transistor of FIG. 1.

FIG. 6A is a plan view of a DRAM device including a conventional 4F2 structure vertical channel transistor, and FIG. 6B is a plan view of a DRAM device including a vertical channel transistor in a case where the spacing between adjacent word lines or bit lines is reduced by half.

### DETAILED DESCRIPTION OF EXEMPLARY EMBODIMENTS

Hereinafter, exemplary embodiments will be described in detail with reference to the accompanying drawings. However, the descriptions herein may be embodied in many different forms and should not be construed as limited to the embodiments set forth herein.

Throughout the specification, when a part is “connected” to another part, this includes not only “directly connected” cases but also “indirectly connected” cases with other members interposed between them. Also, when a member is described as being “on”, “above”, “on top of”, “under”, “below”, or “at the bottom of” another member, this includes not only cases where the member is in contact with the other member but also cases where another member exists between the two members.

Throughout this specification, when a part “comprises” or “includes” a certain component, it means that it can further include other components, not excluding other components, unless otherwise specified.

The embodiments described in this specification will be explained with reference to perspective views, cross-sectional views, etc., which are ideal exemplary diagrams of the present invention. Also, throughout the specification, the same reference numerals denote the same constituent elements. At this time, detailed descriptions of known functions and configurations that could obscure the gist of the present invention have been omitted.

And, in each drawing illustrated in the present invention, each constituent element may be somewhat exaggerated or reduced for convenience of explanation. Furthermore, the embodiments of the present invention are not limited to the specific forms shown, but also include changes in form that may be generated according to the manufacturing process.

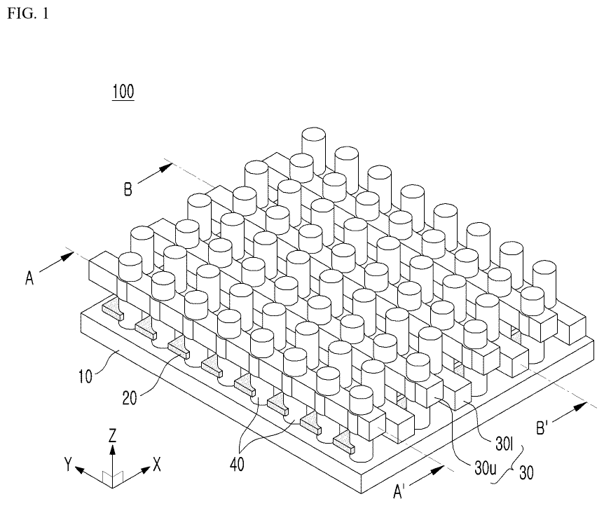

FIG. 1 is a perspective view schematically illustrating a vertical channel transistor according to an embodiment of the present invention. Referring to FIG. 1, the vertical channel transistor (100) according to an embodiment of the present invention includes: a substrate (10); a plurality of channel patterns (40) arranged in a honeycomb structure on the substrate (10), each protruding in a vertical direction (e.g., z-axis direction), and including an upper electrode (40u) and a lower electrode (40l), with the region between the upper electrode (40u) and the lower electrode (40l) being a body region; a plurality of bit lines (20) contacting one side surface of the lower electrode (40l), oriented in a first horizontal direction (e.g., x-axis direction), and arranged parallel to each other at a predetermined interval; a plurality of word lines (30) contacting the body region, oriented in a second horizontal direction (e.g., y-axis direction) perpendicular to the first horizontal direction, and arranged parallel to each other at a predetermined interval; and a gate insulating pattern (not shown) located between the plurality of channel patterns (40) and the plurality of word lines (30).

The plurality of word lines (30) include first and second word lines (30u and 30l) disposed at different heights from each other, and the first and second word lines (30u and 30l) are alternately arranged with each other in the first horizontal direction (e.g., x-axis direction). A plurality of channel patterns contacting a single word line are arranged in a straight line, and a plurality of channel patterns contacting a single bit line are arranged in a zigzag.

The vertical channel transistor (100) corresponds to the transistor part of a DRAM cell, which consists of one transistor and one capacitor. A DRAM device (200) is implemented by arranging a plurality of vertical channel transistors (100) in a matrix form. A plurality of channel patterns (40) are disposed at the intersections of the plurality of bit lines (20) and the plurality of word lines (30u and 30l).

Electrodes (not shown) are formed on the top and bottom of the plurality of channel patterns (40), respectively. The region between the upper electrode (40u) and the lower electrode (40l) is a body region (not shown), which has the same polarity as the substrate (10), while the upper electrode (40u) and the lower electrode (40l) have a different polarity from the substrate (10). For example, if the substrate (10) is a p-type semiconductor substrate, the body region has p-type polarity, and the upper electrode (40u) and the lower electrode (40l) have n-type polarity. In this case, the upper electrode (40u) and the lower electrode (40l) can be formed by implanting n-type impurity ions into the top and bottom of the channel pattern (40), respectively, and performing drive-in diffusion.

A gate (50) is formed to surround the side of the channel pattern (40) between the upper electrode and the lower electrode, and the gate (50) may be composed of a gate insulating pattern (52) and a gate conductive pattern (54).

The plurality of word lines (30u and 30l) include the first word line (30u) and the second word line (30l) disposed at different heights from each other, and the first and second word lines are alternately arranged with each other in the first horizontal direction (e.g., x-axis direction). In conventional vertical channel transistors, the plurality of word lines are arranged side-by-side at substantially the same height, posing a physical limitation in increasing the capacity per unit area.

However, in the present invention, adjacent word lines are disposed at different heights, which allows the minimum feature size (F) to be easily reduced. As a result, there is an advantage in that capacity per unit area can be increased and integration density can be improved.

The first and second word lines (30u and 30l) may be independently formed of at least one material from metals, semiconductors, and alloys. They may be formed of the same material or different materials from each other. Spacers (not shown) may be provided on the sidewalls of the first and second word lines (30u and 30l), and the spacers can serve to prevent contact with other channel patterns (40) that are not interconnected by the first and second word lines (30u and 30l).

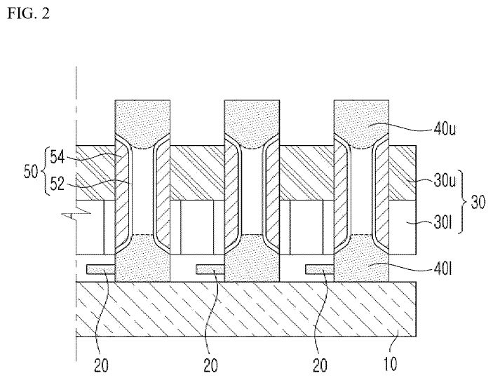

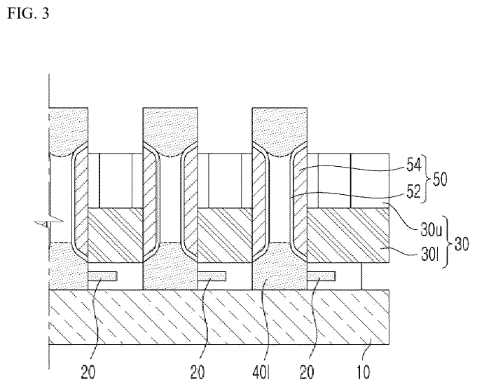

FIG. 2 is a cross-sectional view taken along line A-A′ of FIG. 1, and FIG. 3 is a cross-sectional view taken along line B-B′ of FIG. 1.

The substrate (10) may include, for example, a Group IV semiconductor material such as silicon (Si), germanium (Ge), silicon germanium (SiGe), or silicon carbide (SiC), a Group III-V semiconductor material such as gallium arsenide (GaAs), indium arsenide (InAs), or indium phosphide (InP), an oxide semiconductor, a nitride semiconductor, or an oxynitride semiconductor. Specifically, the substrate may be a silicon substrate doped with p-type impurities, but is not limited thereto.

Each of the plurality of channel patterns (40) is formed to extend substantially vertically from the substrate (10). In other words, the channel pattern (40) may be provided in a pillar shape protruding in the vertical direction (e.g., z-axis direction) from the upper surface of the substrate (10). Each channel pattern (40) may be formed integrally with the substrate (10), and accordingly, may be made of the same semiconductor material as the substrate (10).

The plurality of channel patterns (40) are arranged in a honeycomb structure on the plane of the substrate (10) (i.e., the XY plane). The honeycomb structure refers to a pattern shape arranged at the center and vertices of a hexagon, and accordingly, the arrangement between adjacent channel patterns forms a zigzag shape.

Each channel pattern (40) includes regions doped with impurities at its upper and lower ends to serve as the source/drain and channel of the transistor. More specifically, an upper electrode (40u) is formed at the top of the channel pattern (40) and a lower electrode (40l) is formed at the bottom. The upper electrode (40u) and the lower electrode (40l) can be formed by implanting n-type impurity ions into the upper and lower portions of the channel pattern (40), respectively, and performing a thermal diffusion process. At this time, a separate mask process may be used to designate the positions of the upper electrode (40u) and the lower electrode (40l), and it is controlled so that the impurity diffusion region remaining after the upper/lower electrode formation excludes the body region located in the middle of the channel pattern (40).

The region between the upper electrode (40u) and the lower electrode (40l) corresponds to the body region of the transistor, and the body region has the same polarity (p-type) as the substrate (10), whereas the upper electrode (40u) and the lower electrode (40l) have the opposite polarity (n-type) to the substrate (10). If necessary, the roles of the upper electrode (40u) and the lower electrode (40l) can be interchanged. For example, depending on the operation mode, the upper electrode (40u) may function as a source or drain, and the lower electrode (40l) may perform the counterpart role.

The lower electrode (40l) is electrically connected to the bit line (20), and the upper electrode (40u) is electrically connected to a capacitor (not shown), which will be described later.

A gate (50) is formed over the side surface of the channel pattern, between the upper electrode (40u) and the lower electrode (40l) of the channel pattern (40). The gate (50) corresponds to the gate electrode of the transistor surrounding the body region of the channel pattern, and may include a gate insulating pattern (52) and a gate conductive pattern (54).

The gate insulating pattern (52) is an insulating film formed along the side surface of the channel pattern (40) and may be made of a dielectric material such as silicon oxide (SiO₂) or silicon nitride (Si₃N₄). The gate conductive pattern (54) is a conductive film formed on the outside of the gate insulating pattern (52) and may be made of a conductive material such as polysilicon, metal, or metal silicide.

The gate (50) extends in the vertical direction, wrapping around the body region of the channel pattern (40), and its height is preferably formed to be greater than the combined height of the first and second word lines (30u, 30l) to be described later. This is to ensure that the total height of the gate (50) can cover both word line layers, allowing the word lines to connect to the gate (50) at different heights.

For example, the gate (50) may extend over the entire height of the channel pattern, so that the gate conductive pattern (54) has a continuous structure that is not vertically divided. Alternatively, the gate conductive pattern (54) may be divided into two parts in the vertical direction, formed at heights corresponding to the first word line and the second word line, respectively. In the latter case, the gate (50) takes the form of two gate electrodes connected in series vertically, and a suitable structure can be selected according to the manufacturing process and driving method.

A part of each channel pattern (40) may be in contact with the p-type region of the substrate (10). For example, at least a part of the base portion or the outer portion of the channel pattern (40) may be formed to be continuously connected to the substrate (10). Through this structure, by applying a predetermined bias voltage to the substrate (10), a back-bias is applied to the body region of the channel pattern (40), so that the transistor's body is not floating and can be maintained at a stable potential. Consequently, the unwanted floating body effect is suppressed, which can reduce threshold voltage variations or the occurrence of leakage paths in the transistor.

The bit line (20) is a wiring that connects the lower electrodes (40l) of each memory cell in the vertical channel transistor, extending along the first horizontal direction (e.g., x-axis direction). Referring to FIG. 2, the bit line (20) is formed along the side surface of the lower electrode (40l) of the channel pattern (40), not inside the substrate (10). That is, the bit line (20) has a structure that is spaced apart from the substrate (10) by a predetermined gap and contacts the lower part of the channel pattern (40).

The bit line (20) can be formed by a method of depositing a metal material, instead of implanting impurities into the semiconductor substrate. For example, the bit line (20) may be formed of a metal such as tungsten (W), aluminum (Al), or copper (Cu), or a silicide material. In such a metal bit line structure, the line resistance can be significantly lowered compared to a diffusion bit line formed inside a semiconductor substrate.

Furthermore, since the bit line and the substrate are insulated, the parasitic capacitance of the bit line can be reduced. Therefore, the signal transmission delay (RC delay) through the bit line can be improved, and the strength of the cell signal as seen from the sense amplifier side is enhanced.

Also, the bit line (20) may be formed by micro-patterning a conductive layer made of metal or its alloy material. For example, the bit line (20) can be a metal wiring made by forming an insulating film as a liner in a trench provided in the substrate (10), then depositing a metal such as tungsten or aluminum and etching it. Such a metal bit line (20) has lower resistance and less capacitance compared to a conventional bit line formed as a diffusion region inside the substrate (10), thus providing superior signal transmission characteristics.

Meanwhile, the bit line (20) is formed on the same plane as the substrate (10), but it can be electrically isolated from the substrate (10) by insulation separation through the trench or by diode isolation through a pn junction. That is, since the lower electrode (40l) that the bit line (20) contacts is n-type semiconductor and the substrate (10) is p-type semiconductor, it can be configured such that no current flows between the bit line and the substrate as long as the pn junction between them is not forward-biased. Therefore, the bit line (20) is designed to be electrically connected only to the lower electrode (40l) and not to affect the surrounding substrate region.

The plurality of word lines (30u, 30l) constitute the gate signal lines of the memory cell transistors and extend along the second horizontal direction (e.g., y-axis direction). In the present invention, the word lines are not formed on a single plane but are implemented as a first word line (30u) and a second word line (30l) formed at two different heights.

Referring to FIGS. 2 and 3, the second word line (30l) is formed to surround the lower region of the gate (50) formed on the side of the channel pattern (40), and the first word line (30u) is formed to surround the region above that, on the gate (50). That is, in the part surrounding the gate (50) of each channel pattern (40), the second word line (30l) is disposed on the lower side, and the first word line (30u) is disposed somewhat on the upper side, each connecting to the gate (50) of the channel pattern.

By forming the first word line (30u) and the second word line (30l) at different heights in this way, adjacent word lines along the first horizontal direction alternately have different heights. Consequently, the minimum spacing required between word lines on the same plane can be relaxed, allowing the word line pitch in the cell layout to be reduced.

The first word line (30u) and the second word line (30l) are electrically independent, individual lines. Each word line (30u, 30l) can be formed of a conductive material, for example, a metal such as polysilicon, tungsten, copper, aluminum, molybdenum, or titanium, or a silicide, or an alloy thereof. However, since the two word line layers are formed in different process steps, they do not necessarily need to be formed of the same material.

Depending on the embodiment, the first word line (30u) and the second word line (30l) may be formed of the same material, or they may be formed of different materials. For example, a modification is possible where the lower layer, the second word line (30l), is formed of polysilicon, and the upper layer, the first word line (30u), is formed of metal.

The first and second word lines (30u, 30l) are arranged while contacting the gate (50) of the channel pattern (40). To prevent unintended interference with other channels, spacer insulating films (not shown) may be provided on the sidewalls of the word lines. For example, insulating spacers can be formed on the sidewalls of the first word line (30u) and the second word line (30l) to physically separate them from the gates (50) of adjacent channel patterns (40) that are not connected to that word line. This allows each word line to selectively control only its corresponding channel patterns and avoid affecting the channels of adjacent cells.

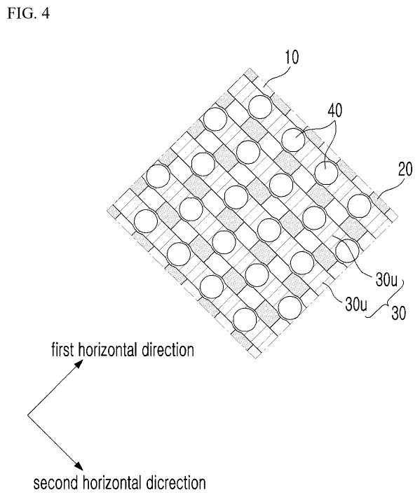

FIG. 4 is a schematic plan view of the vertical channel transistor of FIG. 1. FIG. 4 omits the illustration of capacitors and wirings connected to the top of the channel patterns (40), focusing on the arrangement structure of the channel patterns (40).

Referring to FIG. 4, the plurality of channel patterns (40) are arranged in a honeycomb structure on the bit line (20). Here, the honeycomb structure refers to a structure where channel patterns are placed at the center point and the six vertices of a hexagon, such that each channel pattern located at the six vertices becomes the center point of each of the 6 neighboring hexagons. In the honeycomb structure, the hexagon may be a regular hexagon, and the 6 triangles sharing the center point may all be equilateral triangles.

In FIG. 4, individual bit lines (20) extend in a line in the x-axis direction, and channel patterns (40) are arranged alternately along both edges thereof. The plurality of channel patterns (40) connected to one bit line (20) are arranged crossing left and right along the direction of the bit line, forming a zigzag shape.

On the other hand, the plurality of channel patterns (40) connected to one word line (30uor 30l) are arranged in a line in the y-axis direction, along which the word line extends. For example, the channel patterns whose gates (50) are driven by the first word line (30u) are aligned in a straight line on the y-axis, and the channel patterns driven by the adjacent second word line (30l) are located in between them.

This arrangement efficiently reduces the spacing between adjacent cells, implementing a sub-4F² structure layout (e.g., 3.5F2) with a cell area of 4F² or less. That is, by arranging the plurality of channel patterns (40) in a honeycomb structure, a 3.5F2 structure can be achieved without adjusting the width of the first conductive lines (20l and 20u), the width of the second conductive line (30), and the spacing between adjacent first conductive lines (20). For example, when the diameter of each channel pattern (40), the width of the bit line (20), the width of the word lines (30u and 30l), and the spacing between adjacent bit lines (20) are all equal to F, the area of the parallelogram connecting four channel patterns is about 3.464F² (=2F×2Fsin60°).

Consequently, there is an advantage in that the 3.5F2 structure can be easily achieved without increasing the bit line capacitance (Cb), bit line-word line capacitance, and bit line-substrate capacitance, that is, while maintaining the ratio of bit line capacitance to cell capacitance (Cb/Cs) at the same level as conventional ones. When the diameter of each channel pattern (40), the width of the bit line (20), and the spacing between adjacent bit lines (20) are all equal to F, the inner half of each channel pattern (40) is located on the bit line (20).

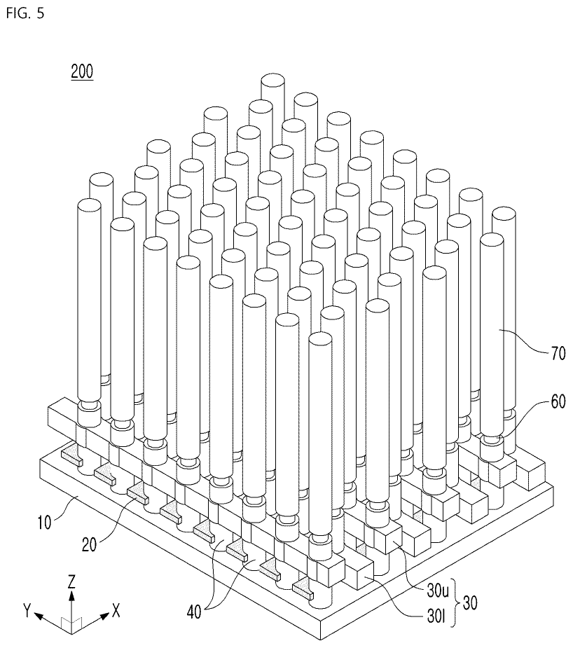

FIG. 5 is a perspective view schematically illustrating a DRAM device including the vertical channel transistor of FIG. 1. Referring to FIG. 5, a capacitor (70) is connected to the upper part of each vertical channel transistor (100). The capacitor (70) is a device for securing the data storage capacity of the memory cell and is electrically connected to the upper electrode (40u) of the channel pattern (40).

The capacitor (70) may be, for example, a stacked capacitor composed of a cylinder-shaped lower electrode, a dielectric layer, and an upper electrode. Although not shown, the upper electrodes of the plurality of memory cell capacitors may be connected to a common potential (node). The lower electrode of the capacitor (70) is connected to the upper electrode (40u) of the channel pattern (40) to form a storage node, and the upper electrode of the capacitor (70) operates as a common plate electrode. Meanwhile, the lower electrode (40l) of the channel pattern (40) is connected to the bit line (20) as described above.

In this way, the vertical channel transistor (100) and the capacitor (70) are combined to form one memory cell, and these memory cells are arranged in an X-Y matrix form to constitute the DRAM device (200). The DRAM device (200) is addressed by the plurality of bit lines (20) and the plurality of word lines (30u, 30l). By turning on the transistor of the selected cell, data stored in the capacitor (70) can be read out to the bit line (20) (Bitline Sensing), or conversely, data can be stored in the capacitor via the bit line.

A contact plug (60) may be further interposed between the capacitor (70) and the channel pattern (40). Through this, the DRAM device (200) utilizing the vertical channel transistor (100) as a memory cell is constructed. Such a vertical channel transistor (100) is versatile enough to be applicable not only to the memory devices described above but also to transistors in non-memory devices such as a central processing unit (CPU).

Hereinafter, the technical reason why the minimum feature size F can be easily reduced because adjacent word lines are disposed at different heights from the bit line will be described in more detail.

In the field of DRAM devices, the minimum feature size F is an important factor that determines the integration density and performance of the device. The minimum feature size F means the smallest line width that can be drawn in a semiconductor circuit, and is generally the smallest of (1) the width of the word line, (2) the width of the bit line, (3) the spacing between adjacent word lines, and (4) the spacing between adjacent bit lines. The smaller the minimum feature size F, the higher the transistor density of the semiconductor chip, the smaller the chip size, and the lower the power consumption. Therefore, technological development in the DRAM device field is moving in the direction of adopting the smallest possible minimum feature size F.

However, this minimum feature size cannot be reduced indefinitely and is usually determined by the level of technological development at the time of manufacturing. Specifically, it is determined by the resolution of photolithography equipment and the quality and performance of the photoresist.

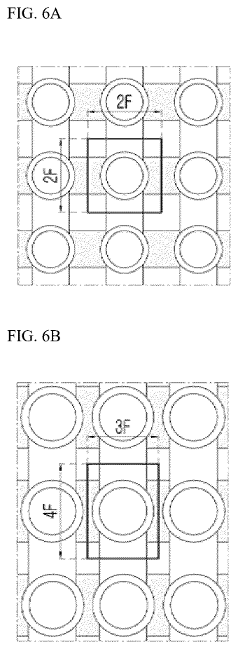

FIG. 6A is a plan view of a DRAM device including a conventional 4F2 structure vertical channel transistor. In FIG. 6A, (1) the width of the word line, (2) the width of the bit line, (3) the spacing between adjacent word lines, and (4) the spacing between adjacent bit lines are all set to F, thus having a 4F2 structure.

FIG. 6B is a plan view of a DRAM device including a vertical channel transistor, manufactured by reducing (3) the spacing between adjacent word lines to half (½) compared to (1) the width of the word line, (2) the width of the bit line, and (4) the spacing between adjacent bit lines. In this case, (3) the spacing between adjacent word lines becomes the minimum feature size F. Since this minimum feature size F is determined by the level of technological development at the time of manufacturing, it ultimately results in an increase in the unit cell area (12F2=4F×3F). That is, adjusting the spacing between adjacent word lines to reduce the unit cell area is by no means desirable.

However, in the present invention, as long as the spacing between adjacent first word lines and the spacing between adjacent second word lines are each equal to or greater than the minimum feature size F, the horizontal spacing between an adjacent first word line and second word line can be adjusted arbitrarily. This is because word lines formed on different planes (different heights) are formed in different process steps, so they are not affected by the minimum feature size determined by the level of technology at the time of manufacturing. Theoretically, the horizontal spacing between an adjacent first word line and second word line can be adjusted down to ½F.

Therefore, the DRAM device according to an aspect of the present invention has the advantage of achieving an improved capacity per unit area compared to the capacity per unit area generally achievable at the level of technological advancement at the time of manufacturing.

The DRAM device according to an aspect of the present invention has an advantage in that the bit line resistance is reduced by forming the bit line from a conductive material such as metal or silicide. In addition, there is an effect of improving the sensing margin of the cell by reducing the parasitic capacitance of the bit line. Furthermore, by forming the bit line through a deposition process rather than ion implantation, there are advantages in that the process difficulty is alleviated and manufacturing uniformity is improved. Moreover, by applying a back-bias to the body region of the channel pattern through the substrate, the floating body effect is suppressed, thereby increasing the stability of cell operation. Also, the reduction in bit line resistance and the increase in the contact area between the bit line and the lower electrode reduce RC delay, thereby improving the operating speed of the device. Furthermore, by forming adjacent word lines at different heights, the minimum spacing between word lines can be reduced. Therefore, the DRAM device according to an aspect of the present invention has the advantage of increasing the cell capacity per unit area, thereby improving integration density. The effects of one aspect of the present invention are not limited to the effects described above, and should be understood to include all effects that can be inferred from the configurations described in the detailed description or claims of this specification.

The foregoing description in this specification is for illustrative purposes, and those of ordinary skill in the art to which this aspect of the specification pertains will be able to understand that easy modifications into other specific forms are possible without changing the technical spirit or essential features described in this specification. Therefore, the embodiments described above should be understood as exemplary in all respects and not restrictive. For example, each component described as a single unit may be implemented in a distributed manner, and likewise, components described as distributed may be implemented in a combined form. The scope of this specification is indicated by the claims described below, and all changes or modified forms derived from the meaning and scope of the claims and their equivalent concepts should be interpreted as being included in the scope of this specification.

What is claimed is:

1. A DRAM device, comprising:
a substrate;
a plurality of channel patterns arranged in a honeycomb structure on the substrate, each extending in a vertical direction, wherein each channel pattern includes an upper electrode and a lower electrode, and a region between the upper electrode and the lower electrode is a body region;
a plurality of bit lines in contact with one side surface of the lower electrode, oriented in a first horizontal direction, and arranged parallel to each other at a predetermined interval;
a plurality of word lines in contact with the body region, oriented in a second horizontal direction perpendicular to the first horizontal direction, and arranged parallel to each other at a predetermined interval; and
a gate insulating pattern positioned between the plurality of channel patterns and the plurality of word lines;
wherein the plurality of word lines include first and second word lines arranged at mutually different heights, and the first and second word lines are alternately provided in the first horizontal direction, and
wherein a plurality of channel patterns in contact with a single word line are arranged in a straight line, and a plurality of channel patterns in contact with a single bit line are arranged in a zigzag, and having a layout of a 3.5F2 structure.

2. The DRAM device of claim 1, wherein each of the plurality of channel patterns includes an upper electrode and a lower electrode, and the lower electrode is in contact with the bit line.

3. The DRAM device of claim 1, wherein the bit line includes a metal or silicide material.

4. The DRAM device of claim 1, further comprising a gate electrode provided between the word line and the gate insulating pattern.
